(19) United States
(12) Patent Application Publication
(10) Pub. No.: US 2026/0024478 A1
(43) Pub. Date: Jan. 22, 2026

(54) DISPLAY DEVICE AND ELECTRONIC DEVICE INCLUDING THE SAME

(71) Applicant: Samsung Display Co., Ltd., Yongin-si (KR)

(72) Inventors: JUNHYUN PARK, Yongin-si (KR); SUNKWUN SON, Yongin-si (KR); CHEOL-GON LEE, Yongin-si (KR); NAHYEON CHA, Yongin-si (KR)

(21) Appl. No.: 19/213,838

(22) Filed: May 20, 2025

(30) Foreign Application Priority Data
Jul. 16, 2024 (KR) 10-2024-0093848

(51) Int. Cl. G09G 3/20

(52) U.S. Cl. CPC G09G 3/2003; G09G 2300/0426; G09G 2310/08; G09G 2330/021

(57) ABSTRACT

A display device includes a first data line extending in a first direction, and configured to sequentially receive a first data signal and a second data signal, a first gate line configured to receive a first gate signal activated for a first active period, a second gate line configured to receive a second gate signal activated for a second active period, a first pixel including a first pixel circuit connected to the first data line and to the first gate line, and a first light-emitting element connected to the first pixel circuit, and a second pixel including a second pixel circuit connected to the first data line and to the second gate line, and a second light-emitting element connected to the second pixel circuit, wherein the first and second pixel circuits are in a same pixel row adjacent to each other in a second direction.

### CROSS-REFERENCE TO RELATED APPLICATION

The present application claims priority to, and the benefit of, Korean Patent Application No. 10-2024-0093848, filed on Jul. 16, 2024, in the Korean Intellectual Property Office, the entire disclosure of which is incorporated herein by reference.

### BACKGROUND

Embodiments of the present disclosure described herein relate to a display device capable of reducing power consumption and an electronic device including the same.

In general, an electronic device, such as a smart phone, a digital camera, a laptop computer, a navigation, or a smart television, which provides an image for a user, includes a display device to display an image. The display device generates the image and then provides the generated image for the user through a display screen.

The display device includes a plurality of pixels to generate an image, and a driving unit to drive the pixels. Each of the pixels includes a light-emitting element and a pixel circuit connected to the light-emitting element. The pixel circuit may be driven by the driving unit such that the light-emitting element emits light.

The layout design of the pixel circuit and the light-emitting element has been developed toward maximizing or improving a light-emitting efficiency while increasing a resolution in a confined space.

### SUMMARY

Embodiments of the present disclosure provide a display device capable of reducing the width of a bezel, and capable of reducing power consumption, and an electronic device including the same.

According to one feature of the present disclosure, a display device includes a first data line extending in a first direction, and configured to sequentially receive a first data signal and a second data signal, a first gate line configured to receive a first gate signal activated for a first active period, a second gate line configured to receive a second gate signal activated for a second active period, a first pixel including a first pixel circuit connected to the first data line and to the first gate line, and a first light-emitting element connected to the first pixel circuit, and a second pixel including a second pixel circuit connected to the first data line and to the second gate line, and a second light-emitting element connected to the second pixel circuit, wherein the first pixel circuit and the second pixel circuit are in a same pixel row adjacent to each other in a second direction crossing the first direction.

A horizontal scan period may be defined by the first active period and the second active period, and may include a first period and a second period.

The first active period and the second active period may have a duration corresponding to ‘k’ times the horizontal scan period, ‘k’ being a natural number equal to or greater than 1.

The first active period and the second active period may overlap, wherein the first gate signal and the second gate signal have an active level for the first period, and wherein the first gate signal has an inactive level, and the second gate signal has an active level, for the second period.

The first active period and the second active period may be separate, wherein the first gate signal has an active level, and the second gate signal has an inactive level, for the first period, and wherein the first gate signal has an inactive level, and the second gate signal has an active level, for the second period.

The first data line may be configured to apply the first data signal to the first pixel circuit and to the second pixel circuit for the first period, wherein the first data line is configured to apply the second data signal to the second pixel circuit for the second period.

Color information of the first data signal may be different from color information of the second data signal.

The first pixel circuit may be connected to the first light-emitting element through a connection electrode, wherein the second pixel circuit is connected to the second light-emitting element through a bridge electrode, and wherein the bridge electrode is longer than the connection electrode.

The second light-emitting element may include an anode electrode integral with the bridge electrode.

The second light-emitting element may include an anode electrode at a different layer from the bridge electrode.

The display device may further include a second data line extending in the first direction, and configured to sequentially receive a third data signal and a fourth data signal, a third pixel including a third pixel circuit connected to the second data line and to the first gate line, and a third light-emitting element connected to the third pixel circuit, and a fourth pixel including a fourth pixel circuit connected to the second data line and the second gate line, and a fourth light-emitting element connected to the fourth pixel circuit.

The second data line may be configured to apply the third data signal to the third pixel circuit and to the fourth pixel circuit for the first period, wherein the second data line is configured to apply the fourth data signal to the fourth pixel circuit for the second period.

Color information of the third data signal may be different from color information of the fourth data signal.

Color information of the third data signal may be the same as color information of the fourth data signal.

According to a feature of the present disclosure, an electronic device includes a display device for providing an image, and a processor to control an operation of the display device wherein the display device includes a first data line extending in a first direction, and configured to sequentially receive a first data signal including color information and a second data signal including color information that is the same as the color information of the first data signal, a first gate line configured to receive a first gate signal, a second gate line configured to receive a second gate signal, a first pixel including a first pixel circuit connected to the first data line and to the first gate line, and a first light-emitting element connected to the first pixel circuit through a connection electrode, and a second pixel including a second pixel circuit connected to the first data line and to the second gate line and adjacent to the first pixel circuit in a same pixel row in a second direction crossing the first direction, and a second light-emitting element connected to the second pixel circuit through a bridge electrode that is longer than the connection electrode.

The electronic device may further include a second data line extending in the first direction, and configured to sequentially receive a third data signal and a fourth data signal, a third pixel including a third pixel circuit connected to the second data line and to the first gate line, and a third light-emitting element connected to the third pixel circuit, a fourth pixel including a fourth pixel circuit connected to the second data line and to the second gate line, and a fourth light-emitting element connected to the fourth pixel circuit, wherein the third light-emitting element includes a first sub-anode electrode and a second sub-anode electrode.

Color information of the third data signal may be the same as color information of the fourth data signal.

The bridge electrode may be at a same layer as the first sub-anode electrode and the second sub-anode electrode.

The bridge electrode may be at a different layer from a layer from the first sub-anode electrode and the second sub-anode electrode.

According to one feature of the present disclosure, a display device includes a first data line configured to sequentially receive a first data signal and a second data signal, a second data line configured to sequentially receive a third data signal and a fourth data signal, a first gate line configured to receive a first gate signal activated for a first active period, a second gate line configured to receive a second gate signal activated for a second active period, a first pixel including a first pixel circuit connected to the first data line and to the first gate line, and a first light-emitting element connected to the first pixel circuit, a second pixel including a second pixel circuit connected to the first data line and to the second gate line, and a second light-emitting element connected to the second pixel circuit, a third pixel including a third pixel circuit connected to the second data line and to the first gate line, and a third light-emitting element connected to the third pixel circuit, and a fourth pixel including a fourth pixel circuit connected to the second data line and to the second gate line, and a fourth light-emitting element connected to the fourth pixel circuit, wherein color information of the first data signal is different from color information of the second data signal, which is the same as color information contained in the third data signal, and wherein color information of the fourth data signal is different from the color information of the first data signal and the color information of the second data signal.

### BRIEF DESCRIPTION OF THE DRAWINGS

The above and other objects and features of the present disclosure will become apparent by describing in detail embodiments thereof with reference to the accompanying drawings.

FIG. 1 is a block diagram of a display device according to one or more embodiments of the present disclosure.

FIG. 2 is a cross-sectional view of a display panel according to one or more embodiments of the present disclosure.

FIG. 3 is a block diagram of pixels according to one or more embodiments of the present disclosure.

FIG. 4A is a timing diagram illustrating first and second gate signals respectively applied to first and second gate lines according to one or more embodiments of the present disclosure.

FIG. 4B is a timing diagram illustrating first and second gate signals respectively applied to first and second gate lines according to one or more embodiments of the present disclosure.

FIG. 5 is a block diagram of pixels according to one or more embodiments of the present disclosure.

FIG. 6 is a block diagram illustrating pixel circuits and gate drivers according to one or more embodiments of the present disclosure.

FIG. 7 is a timing diagram illustrating first and second gate signals respectively applied to first and second gate lines according to one or more embodiments of the present disclosure.

FIG. 8A is a plan view illustrating a plurality of pixels according to one or more embodiments of the present disclosure.

FIG. 8B is a plan view of light-emitting elements according to one or more embodiments of the present disclosure.

FIG. 9A is a plan view of light-emitting elements according to one or more embodiments of the present disclosure.

FIG. 9B is a cross-sectional view of a third light-emitting element taken along line I-I′ of FIG. 9A.

FIG. 10 is a cross-sectional view of a third light-emitting element according to one or more embodiments of the present disclosure.

FIG. 11 is a block diagram illustrating the electronic device according to an embodiment of the present disclosure.

FIG. 12 are schematic views illustrating electronic devices according to various embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and

similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

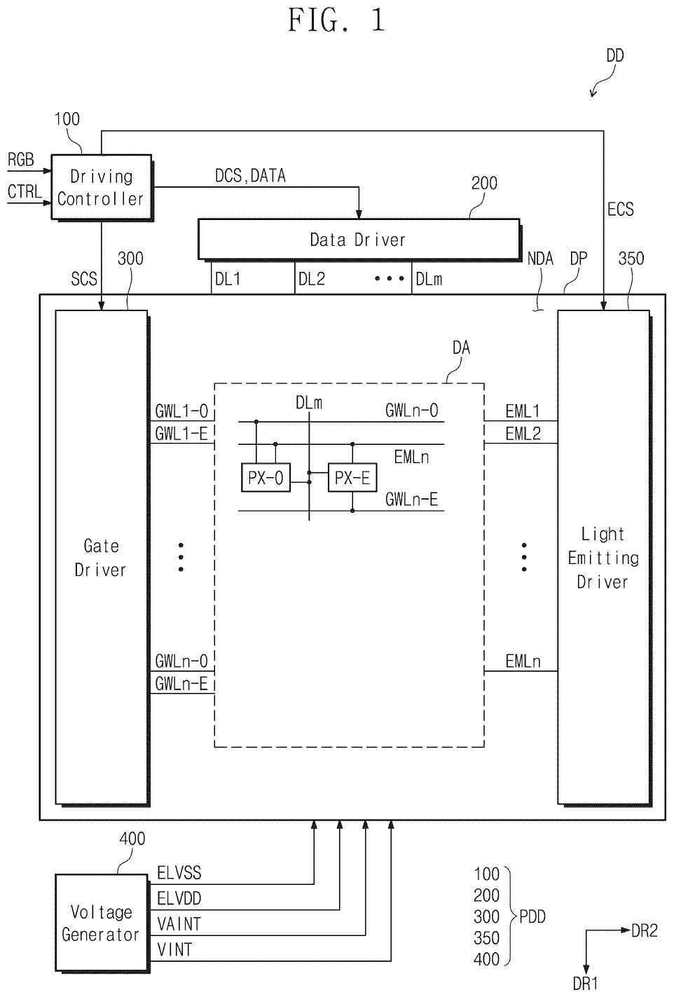

FIG. 1 is a block diagram of a display device according to one or more embodiments of the present disclosure.

Referring to FIG. 1, a display device DD may include a display panel DP and a panel driver PDD. The panel driver PDD may include a driving controller 100, a data driver 200, a gate driver 300, a light-emitting driver 350, and a voltage generator 400.

The display panel DP may include a display region DA and a non-display region NDA which surrounds at least a portion of the display region DA. The display panel DP may include pixels PX-O and PX-E located in the display region DA. The display panel DP may further include gate lines GWL1-O to GWLn-O, and GWL1-E to GWLn-E, light-emitting control lines EML1 to EMLn, and data lines DL1 to DLm.

The driving controller 100 receives an image signal RGB and a control signal CTRL. The driving controller 100 generates image data DATA by transforming a data format of the image signal RGB to be matched to the interface specification of the data driver 200. The driving controller 100 outputs a first driving control signal SCS, a second driving control signal DCS, and a third driving control signal ECS.

The data driver 200 receives the second driving control signal DCS and the image data DATA from the driving controller 100. The data driver 200 transforms the image data DATA into data signals, and outputs the data signals to data lines DL1 to DLm. The data signals refer to analog voltages corresponding to grayscale values of the image data DATA. Each of the data lines DL1 to DLm may extend in a first direction DR1, and the data lines DL1 to DLm may be arranged in a second direction DR2. In this case, ‘m’ may be an integer (or a natural number) equal to or greater than ‘1’.

The gate driver 300 receives the first driving control signal SCS from the driving controller 100. The gate driver 300 may be connected to the gate lines GWL1-O to GWLn-O, and GWL1-E to GWLn-E. The gate driver 300 may output scan signals to the gate lines GWL1-O to GWLn-O, and GWL1-E to GWLn-E, respectively, in response to the first driving control signal SCS. The gate lines GWL1-O to GWLn-O, and GWL1-E to GWLn-E may extend in the second direction DR2, and may be arranged in the first direction DR1. In this case, ‘n’ may be an integer (or a natural number) equal to or greater than ‘1’.

The gate lines GWL1-O to GWLn-O, and GWL1-E to GWLn-E may include the odd gate lines GWL1-O to GWLn-O and the even gate lines GWL1-E to GWLn-E. The odd gate lines GWL1-O to GWLn-O and the even gate lines GWL1-E to GWLn-E may be alternately arranged in the first direction DR1. Each of the pixels PX-O and PX-E may be connected to one of the odd gate lines GWL1-O to GWLn-O or one of the even gate lines GWL1-E to GWLn-E.

Alternatively, the light-emitting driver 350 may be connected to the light-emitting control lines EML1 to EMLn. The light-emitting driver 350 may output light-emitting control signals to the light-emitting control lines EML1 to EMLn, in response to the third driving control signal ECS from the driving controller 100.

The voltage generator 400 (or a power supply unit) may generate voltages suitable for operations of the display panel DP, and may supply the voltages to the display panel DP. According to one or more embodiments of the present disclosure, the voltage generator 400 may generate a first driving voltage ELVDD, a second driving voltage ELVSS, a first initializing voltage VINT, and a second initializing voltage VAINT.

Each of the plurality of pixels PX-O and PX-E may be electrically connected to relevant gate lines of the gate lines GWL1-O to GWLn-O, and GWL1-E to GWLn-E, to a relevant one of the light-emitting control lines EML1 to EMLn, and to a relevant one of the data lines DL1 to DLm. For example, the odd pixels PX-O of the pixels PX-O and PX-E in an n-th row may be connected to the n-th odd gate line GWLn-O and the n-th light-emitting control line EMLn. The even pixels PX-E of the pixels PX-O and PX-E in the n-th row may be connected to the n-th even gate line GWLn-O and the n-th light-emitting control line EMLn. The pixels PX-O and PX-E in the m-th column may be connected to the m-th data line DLm.

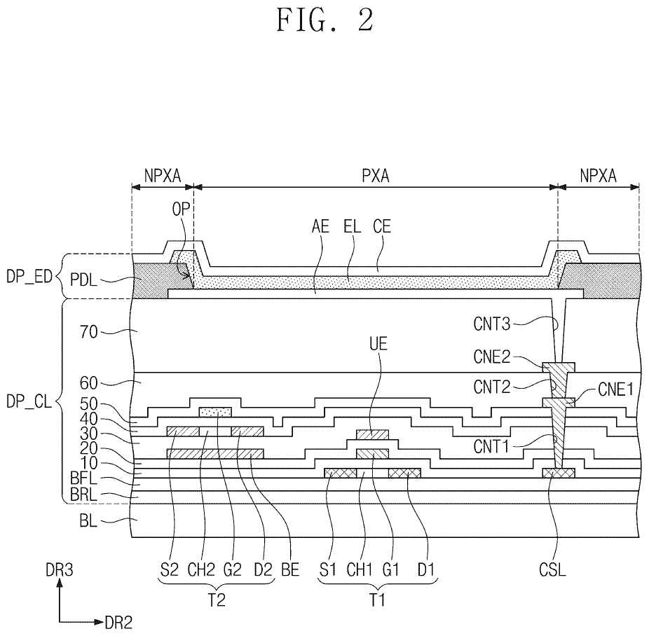

FIG. 2 is a cross-sectional view of a display panel according to one or more embodiments of the present disclosure.

Referring to FIG. 2, the display panel DP may include a base layer BL, a circuit layer DP_CL, and an element layer DP_ED.

The base layer BL may include a synthetic resin layer. The synthetic resin layer may include a thermosetting resin. For example, the synthetic resin layer may be a polyimide-based resin layer, and the material is not particularly limited. The synthetic resin layer may include at least any one of acrylic resin, methacrylic resin, polyisoprene, vinyl resin, epoxy resin, urethane-based resin, cellulosic resin, siloxane-based resin, polyamide resin, or perylene-based resin. In addition, the base layer BL may include a glass substrate, a metal substrate, or an organic/inorganic composite material substrate.

The circuit layer DP_CL may include a barrier layer BRL and/or a buffer layer BFL. The barrier layer BRL reduces or prevents foreign substances from being introduced from the outside. The barrier layer BRL may include a silicon oxide layer and a silicon nitride layer. The silicon oxide layer may include a plurality of silicon oxide layers, and the silicon nitride layer may include a plurality of silicon nitride layers, and the silicon oxide layers and the silicon nitride layers may be alternately stacked.

The buffer layer BFL may be located on the barrier layer BRL. The buffer layer BFL may improve a coupling force between the base layer BL and a semiconductor pattern and/or a conductive pattern. The buffer layer BFL may include a silicon oxide layer and a silicon nitride layer. The silicon oxide layer and the silicon nitride layer may be alternately stacked.

The semiconductor pattern is located on the buffer layer BFL. Hereinafter, the semiconductor pattern directly located on the buffer layer BFL is defined as a first semiconductor pattern. The first semiconductor pattern may include a silicon semiconductor. The first semiconductor pattern may include poly silicon. However, the present disclosure is not limited thereto, and the first semiconductor pattern may include amorphous silicon.

Although FIG. 2 illustrates a portion of the first semiconductor pattern, the first semiconductor pattern may be additionally located in another region of the pixels PX-O and PX-E (see FIG. 1). The first semiconductor pattern may have an electrical property varying depending on whether the first semiconductor pattern is doped. The first semiconductor pattern may include a doping region and a non-doping region. The doping region may be doped with an N-type dopant or a P-type dopant. A transistor in a P type may include a doping region doped with the P-type dopant, and a transistor in an N type may be doping region doped with the N-type dopant.

The doping region is greater than the non-doping region in conductivity, and actually serves as an electrode or a signal line. The non-doping region may actually correspond to an active (or a channel) of the transistor. In other words, a portion of the first semiconductor pattern may be the active of the transistor, another portion of the first semiconductor pattern may be a source or a drain of the transistor, and still another portion of the first semiconductor pattern may be a connection signal line (or a connection electrode).

As illustrated in FIG. 2, a first electrode S1, a channel part CH1, a second electrode D1 of a first transistor T1 are formed from the first semiconductor pattern. The first electrode S1 and the second electrode D1 of the first transistor T1 may extend in directions opposite to each other from the channel part CH1.

A first insulating layer 10 is located on the buffer layer BFL. The first insulating layer 10 overlaps the pixels PX-O and PX-E (see FIG. 1) in common, and covers the first semiconductor pattern. The first insulating layer 10 may be an inorganic layer and/or an organic layer, and may have a single layer structure or a multi-layer structure. The first insulating layer 10 may include at least one of an aluminum oxide, a titanium oxide, a silicon oxide, a silicon oxynitride, a zirconium oxide, or a hafnium oxide. According to one or more embodiments, the first insulating layer 10 may be a single silicon oxide layer. In addition to the first insulating layer 10, the insulating layer of the circuit layer DP_CL, which is to be described below, may be an inorganic layer and/or an organic layer, and may have a single layer structure or a multi-layer structure. The inorganic layer may include at least one of the above-described materials.

The third electrode G1 of the first transistor T1 is located on the first insulating layer 10. The third electrode G1 of the first transistor T1 overlaps the channel part CH1 of the first transistor T1. In the process of doping the first semiconductor pattern, the third electrode G1 of the first transistor T1 may serve as a mask.

A second insulating layer 20 is located on the first insulating layer 10 to cover the third electrode G1. The second insulating layer 20 may overlap (e.g., may be overlapped with) the plurality of pixels PX-O and PX-E in common. The second insulating layer 20 may be an inorganic layer and/or an organic layer, and may have a single layer structure or a multi-layer structure. According to one or more embodiments, the second insulating layer 20 may be a single silicon oxide layer.

An upper electrode UE and a lower electrode BE may be located on the second insulating layer 20. The upper electrode UE may overlap the third electrode G1. The lower electrode BE may overlap a second semiconductor pattern of a second transistor to be described later. The lower electrode BE may be referred to as a bottom gate of the second transistor T2. A portion of the third electrode G1 and the upper electrode UE overlapped with the portion of the third electrode G1 may define a capacitor.

According to one or more embodiments of the present disclosure, the second insulating layer 20 may be substituted to an insulating pattern. The upper electrode UE and the lower electrode BE are located on an insulating pattern. The upper electrode UE and the lower electrode BE may serve as a mask for forming the insulating pattern from the second insulating layer 20.

A third insulating layer 30 is located on the second insulating layer 20 to cover the upper electrode UE and the lower electrode BE. According to one or more embodiments, the third insulating layer 30 may be a single silicon oxide layer. A semiconductor pattern is located on the third insulating layer 30. Hereinafter, the semiconductor pattern directly located on the third insulating layer 30 is defined as a second semiconductor pattern. The second semiconductor pattern may include a metal oxide. The oxide semiconductor may include a crystalline or amorphous oxide semiconductor. For example, the oxide semiconductor may include a metal oxide, such as zinc (Zn), indium (In), gallium (Ga), tin (Sn), titanium (Ti), or a mixture of metal, such as zinc (Zn), indium (In), gallium (Ga), tin (Sn), or titanium (Ti), and the oxide thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), or zinc-tin oxide (ZTO).

Although FIG. 2 illustrates a portion of the second semiconductor pattern, the second semiconductor pattern may be additionally located in another region of the pixels PX-O and PX-E. The second semiconductor pattern may include a plurality of regions which are divided depending on whether the metal oxide is reduced. A region (hereinafter, referred to as a reduction region) in which the metal oxide is reduced has higher conductivity than a region (hereinafter, referred to as a non-reduction region) in which the metal oxide is not reduced. The reduction region actually serves as an electrode or a signal line. The non-reduction region actually corresponds to a channel part of a transistor. In other words, a portion of the second semiconductor pattern may be the channel part of the transistor, and another portion of the second semiconductor pattern may be a first electrode or a second electrode of the transistor.

The circuit layer DP_CL may further include a portion of the semiconductor pattern of the pixel driving circuit. A second transistor T2 of the semiconductor pattern of the pixel driver is illustrated for the convenience of explanation. A first electrode S2, a channel part CH2, and a second electrode D2 of the second transistor T2 are formed from the second semiconductor pattern. According to one or more embodiments, the second semiconductor pattern may include a metal oxide by way of example. The first electrode S2 and the second electrode D2 include metal reduced from a metal oxide semiconductor. The first electrode S2 and the second electrode D2 may include a metal layer having a corresponding thickness from a top surface of the second semiconductor pattern, and including the reduced metal.

A fourth insulating layer 40 is located to cover the first electrode S2, the channel part CH2, and the second electrode D2 of the second transistor T2. The third electrode G2 of the second transistor T2 is located on the fourth insulating layer 40. The third electrode G2 of the second transistor T2 may be referred to as a top gate. The third electrode G2 of the second transistor T2 overlaps the channel part CH2 of the second transistor T2. The third electrode G2 of the second transistor T2 may overlap the lower electrode BE, when viewed in a plan view, and may be connected to the lower electrode BE through a contact hole formed through the third and fourth insulating layers 30 and 40. In other words, the third electrode G2 of the second transistor T2 may be electrically connected to the lower electrode BE.

A fifth insulating layer 50 is located on the fourth insulating layer 40 to cover the third electrode G2 of the second transistor T2. According to one or more embodiments the fifth insulating layer 50 may include a silicon oxide layer and a silicon nitride layer. The fifth insulating layer 50 may include a plurality of silicon oxide layers and a plurality of silicon nitride layers alternately stacked one another.

At least one insulating layer is further located on the fifth insulating layer 50. According to one or more embodiments, a sixth insulating layer 60 may be located on the fifth insulating layer 50. The sixth insulating layer 60 may be an organic layer, and may have a single layer structure or a multi-layer structure. The sixth insulating layer 60 may be a single-layer polyimide-based resin layer. However, the present disclosure is not limited thereto. For example, the sixth insulating layer 60 may include at least one of acrylic resin, methacrylic resin, polyisoprene, vinyl resin, epoxy resin, urethane-based resin, cellulosic resin, siloxane-based resin, polyamide resin, or perylene-based resin.

A first connection electrode CNE1 may be located on the fifth insulating layer 50. The first connection electrode CNE1 may be connected with a connection signal line CSL through a first contact hole CNT1 formed through the first to fifth insulating layers 10 to 50. A second connection electrode CNE2 may be connected to the first connection electrode CNE1 through a second contact hole CNT2 formed through the sixth insulating layer 60.

The first connection electrode CNE1 may be a portion of a first data metal pattern, and the second connection electrode CNE2 may be a portion of a second data metal pattern.

A seventh insulating layer 70 is located on the sixth insulating layer 60 to cover the second connection electrode CNE2. A third contact hole CNT3 may be provided in the seventh insulating layer 70 to partially expose the second connection electrode CNE2.

The element layer DP_ED is located on the circuit layer DP_CL. The element layer DP_ED may include an anode electrode AE. As illustrated in FIG. 2, the anode electrode AE may be connected to the second connection electrode CNE2 through the third contact hole CNT3 formed through the seventh insulating layer 70.

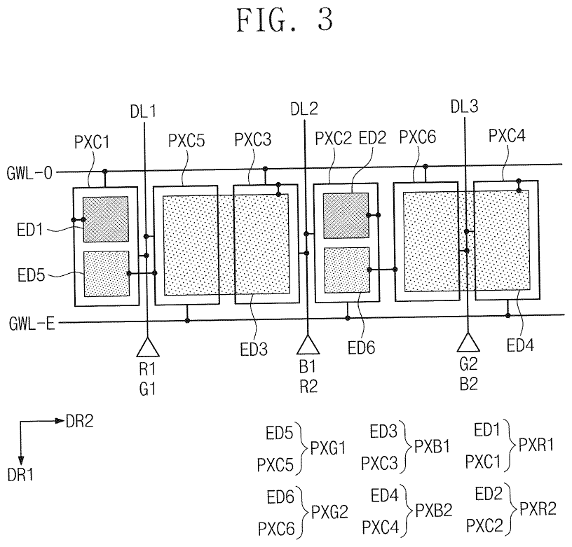

The element layer DP_ED further includes a pixel-defining layer PDL located on the circuit layer DP_CL. The pixel-defining layer PDL may include an opening part OP defined to correspond to light-emitting elements ED1 to ED6 (see FIG. 3). The opening part OP exposes at least a portion of the anode electrode AE.

A light-emitting layer EL is located to correspond to the opening part OP defined in the pixel-defining layer PDL. Although the light-emitting layer EL patterned is illustrated according to one or more embodiments, the present disclosure is not limited thereto. Alternatively, a common light-emitting layer may be located in the plurality of pixels PX-O and PX-E in common. In this case, the common light-emitting layer may generate a white light or a blue light. A cathode electrode CE is located on the light-emitting layer EL. The cathode electrode CE is located on the plurality of pixels PX-O and PX-E in common.

FIG. 3 is a block diagram of pixels according to one or more embodiments of the present disclosure. FIG. 3 illustrates some pixels (e.g., first to sixth pixels) of pixels arranged in a first row. The first pixel may correspond to a first red pixel PXR1, and a second pixel may correspond to a second red pixel PXR2. The third pixel may correspond to a first blue pixel PXB1, and a fourth pixel may correspond to a second blue pixel PXB2. The fifth pixel may correspond to a first green pixel PXG1, and a sixth pixel may correspond to a second green pixel PXG2. Hereinafter, the first to sixth pixels are referred to as the first and second red pixels PXR1 and PXR2, the first and second blue pixels PXB1 and PXB2, and the first and second green pixels PXG1 and PXG2.

Referring to FIG. 3, among the first to sixth pixels PXR1, PXR2, PXB1, PXB2, PXG1, and PXG2, the first and second red pixels PXR1 and PXR2 are red pixels to output a first color light (for example, a red light), the third and fourth blue pixels PXB1 and PXB2 are blue pixels to output a second color light (for example, a blue light), and the fifth and sixth green pixels PXG1 and PXG2 are green pixels to output the third color light (for example, a green light).

The first gate line GWL-O and the second gate line GWL-E extend in the second direction DR2, and are spaced apart from each other in the first direction DR1. The first to sixth pixels PXR1, PXR2, PXB1, PXB2, PXG1, and PXG2 may be arranged in the second direction DR2, and may be interposed between the first gate line GWL-O and the second gate line GWL-E.

The first gate line GWL-O is one gate line of the odd gate lines GWL1-O to GWLn-O (see FIG. 1), and the second gate line GWL-E is one gate line of the even gate lines GWL1-E to GWLn-E (see FIG. 1).

Some (e.g., the first red pixel PXR1, the first blue pixel PXB1, and the second green pixel PXG2) of the first to sixth pixels PXR1, PXR2, PXB1, PXB2, PXG1, and PXG2 may be connected to the first gate line GWL-O, and remaining pixels (e.g., the second red pixel PXR2, the second blue pixel PXB2, and the first green pixel PXG1) of the first to sixth pixels PXR1, PXR2, PXB1, PXB2, PXG1, and PXG2 may be connected to the second gate line GWL-E.

The first to third data lines DL1 to DL3 extend in the first direction DR1 and are arranged in the second direction DR2. The first gate line GWL-O and the second gate line GWL-E may cross the first to third data lines DL1 to DL3. Each of the first to third data lines DL1 to DL3 may be connected to two pixels among the first to sixth pixels PXR1, PXR2, PXB1, PXB2, PXG1, and PXG2 arranged in parallel in the second direction DR2. The first data line DL1 may be connected to the first red pixel PXR1 and the first green pixel PXG1 among the first to sixth pixels PXR1, PXR2, PXB1, PXB2, PXG1, and PXG2. The second data line DL2 may be connected to the second red pixel PXR2 and the first blue pixel PXB1 among the first to sixth pixels PXR1, PXR2, PXB1, PXB2, PXG1, and PXG2. The third data line DL3 may be connected to the second blue pixel PXB2 and the second green pixel PXG2 among the first to sixth pixels PXR1, PXR2, PXB1, PXB2, PXG1, and PXG2.

The first to third data lines DL1 to DL3 may receive data signals from the data driver 200 (see FIG. 1). Each of the data signals may have a voltage level corresponding to an image signal. The data signals may include first and second red data signals R1 and R2, first and second green data signals G1 and G2, and first and second blue data signals B1 and B2. According to one or more embodiments of the present disclosure, the first red data signal R1 and the first green data signal G1 are sequentially applied to the first data line DL1, the first blue data signal B1 and the second red data signal R2 are sequentially applied to the second data line DL2, and the second green data signal G2 and the second blue data signal B2 are sequentially applied to the third data line DL3.

The first red pixel PXR1 may include a first pixel circuit PXC1 connected to the first data line DL1 and to the first gate line GWL-O, and may include a first light-emitting element ED1 connected to the first pixel circuit PXC1. The first light-emitting element ED1 and the first pixel circuit PXC1 may overlap each other in a plan view.

The first green pixel PXG1 may include a fifth pixel circuit PXC5 (e.g., second pixel circuit in the claims) connected to the first data line DL1 and to the second gate line GWL-E, and may include a fifth light-emitting element ED5 (e.g., a second light-emitting element in the claims) connected to the fifth pixel circuit PXC5. The first data line DL1 is interposed between the first pixel circuit PXC1 and the fifth pixel circuit PXC5. The fifth light-emitting element ED5 and the fifth pixel circuit PXC5 may not be overlapped with each other in a plan view (e.g., may be separated in a plan view). However, the present disclosure is not limited thereto. For example, the first light-emitting element ED1 and the first pixel circuit PXC1 may not overlap in a plan view, or the fifth light-emitting element ED5 and the fifth pixel circuit PXC5 may partially overlap each other in a plan view. The first light-emitting element ED1 and the fifth light-emitting element ED5 may be adjacent to each other in the first direction DR1, and the first pixel circuit PXC1 and the fifth pixel circuit PXC5 may be adjacent to each other in the second direction DR2.

The second red pixel PXR2 may include a second pixel circuit PXC2 (e.g., a fourth pixel circuit in the claims) connected to the second data line DL2 and to the second gate line GWL-E, and may include a second light-emitting element ED2 (e.g., a fourth light-emitting element in the claims) connected to the second pixel circuit PXC2. The second light-emitting element ED2 and the second pixel circuit PXC2 may overlap each other, when viewed in a plan view.

The first blue pixel PXB1 may include a third pixel circuit PXC3 connected to the second data line DL2 and to the first gate line GWL-O, and may include a third light-emitting element ED3 connected to the third pixel circuit PXC3. The second data line DL2 is interposed between the third pixel circuit PXC3 and the second pixel circuit PXC2. The third light-emitting element ED3 and the third pixel circuit PXC3 may overlap each other, when viewed in a plan view. However, the present disclosure is not limited thereto. For example, the second light-emitting element ED2 and the second pixel circuit PXC2 may not be overlapped with each other, when viewed in a plan view, or the third light-emitting element ED3 and the third pixel circuit PXC3 may not be overlapped with each other, when viewed in a plan view. The second light-emitting element ED2 and the third light-emitting element ED3 may be adjacent to each other in the second direction DR2, and the second pixel circuit PXC2 and the third pixel circuit PXC3 may be adjacent to each other in the second direction DR2. According to one or more embodiments of the present disclosure, the fifth pixel circuit PXC5 is interposed between the first and third pixel circuits PXC1 and PXC3, and the third pixel circuit PXC3 is interposed between the fifth pixel circuit PXC5 and the second pixel circuit PXC2. The third light-emitting element ED3 may be interposed between the first light-emitting element ED1 and the second light-emitting element ED2.

The second blue pixel PXB2 may include a fourth pixel circuit PXC4 connected to the third data line DL3 and to the second gate line GWL-E, and may include a fourth light-emitting element ED4 connected to the fourth pixel circuit PXC4. The fourth light-emitting element ED4 and the fourth pixel circuit PXC4 may overlap each other, when viewed in a plan view. The second green pixel PXG2 may include a sixth pixel circuit PXC6 connected to the third data line DL3 and to the first gate line GWL-O, and may include a sixth light-emitting element ED6 connected to the sixth pixel circuit PXG2. The sixth light-emitting element ED6 and the sixth pixel circuit PXC6 may not be overlapped with each other, when viewed in a plan view. However, the present disclosure is not limited thereto. For example, the fourth light-emitting element ED4 and the fourth pixel circuit PXC4 may not be overlapped with each other, when viewed in a plan view, or the sixth light-emitting element ED6 and the sixth pixel circuit PXC6 may be partially overlapped with each other, when viewed in a plan view. The fourth light-emitting element ED4 and the sixth light-emitting element ED6 may be adjacent to each other in the second direction DR2, and the fourth pixel circuit PXC4 and the sixth pixel circuit PXC6 may be adjacent to each other in the second direction DR2. According to one or more embodiments of the present disclosure, the second pixel circuit PXC2 is interposed between the third pixel circuit PXC3 and the sixth pixel circuit PXC6, and the sixth pixel circuit PXC6 is interposed between the second pixel circuit PXC2 and the fourth pixel circuit PXC4. The second light-emitting element ED2 and the sixth light-emitting element ED6 may be interposed between the third light-emitting element ED3 and the fourth light-emitting element ED4.

According to one or more embodiments of the present disclosure, the first to sixth pixel circuits PXC1 to PXC6 may be arranged in the same pixel row.

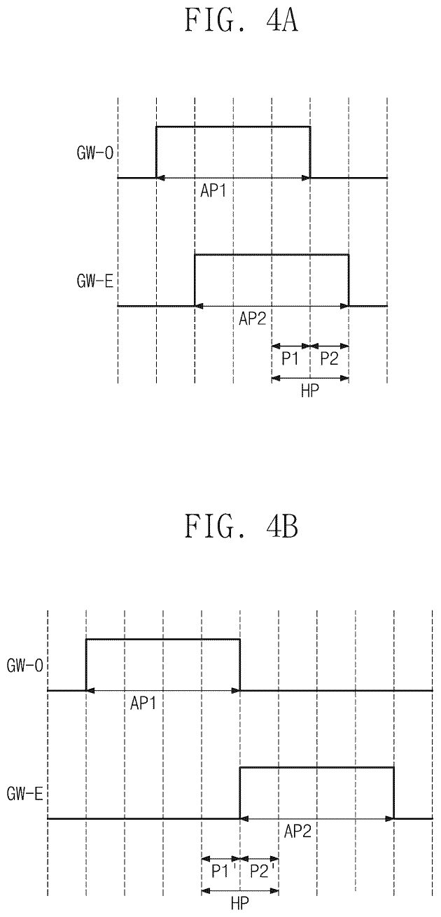

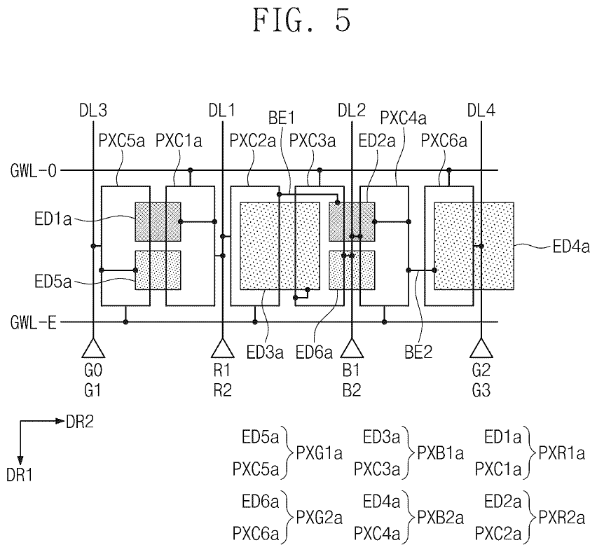

FIG. 4A is a timing diagram illustrating first and second gate signals respectively applied to first and second gate lines according to one or more embodiments of the present disclosure. FIG. 4B is a timing diagram illustrating first and second gate signals respectively applied to first and second gate lines according to one or more embodiments of the present disclosure.

Referring to FIGS. 3, 4A, and 4B, the first gate signal GW-O may include a first active period AP1 having an active level (for example, a high level), and the second gate signal GW-E may include a second active period AP2 having an active level. Each of the first active period AP1 and the second active period AP2 may have a duration corresponding to ‘k’ times a horizontal scan period HP. In this case, ‘k’ may be a natural number. The horizontal scan period HP may be defined as a time suitable to write a data signal into one pixel row. The second gate signal GW-E may be a signal delayed from the first gate signal GW-O, by a half of one horizontal scan period HP.

In FIG. 4A, the first active period AP1 overlapped with the second active period AP2 is illustrated. In FIG. 4B, the first active period AP1, which is not overlapped with (e.g., is separate from) the second active period AP2, is illustrated (e.g., the first active period AP1 and the second active period AP2 are separate). In other words, a starting time point of the first active period AP1 may precede a starting time point of the second active period AP2, and a terminating time point of the first active period AP1 may precede a terminating time point of the second active period AP2.

The horizontal scan period HP may include a first period P1 and a second period P2. The first active period AP1 of the first gate signal GW-O overlaps the first period P1, and the second active period AP2 of the second gate signal GW-E overlaps the first period P1 and the second period P2. In other words, the first gate signal GW-O and the second gate signal GW-E may have the active level for the first period P1, and the first gate signal GW-O has the inactive level and the second gate signal GW-E may have the active level, for the second period P2. Accordingly, the first red pixel PXR1, the first blue pixel PXB1, and the second green pixel PXG2 connected to the first gate line GWL-O may receive the first red data signal R1, the first blue data signal B1, and the second green data signal G2 from the first to third data lines DL1 to DL3, for the first period P1. Because the second gate signal GW-E has the active level for the first period P1, the second red pixel PXR2, the second blue pixel PXB2, and the first green pixel PXG1 connected to the second gate line GWL-E may receive the first red data signal R1, the first blue data signal B1, and the second green data signal G2 from the first to third data lines DL1 to DL3, for the first period P1.

However, according to one or more embodiments of the present disclosure, the first active period AP1 of the first gate signal GW-O may overlap a first period P1′ and may not be overlapped with a second period P2′. The second active period AP2 of the second gate signal GW-E may not be overlapped with the first period P1′ and may overlap the second period P2′. In this case, because the second gate signal GW-E has the non-active level for the first period P1′, the second red pixel PXR2, the second blue pixel PXB2, and the first green pixel PXG1 connected to the second gate line GWL-E may fail to receive the first red data signal R1, the first blue data signal B1, and the second green data signal G2 from the first to third data lines DL1 to DL3, for the first period P1′. In other words, the first gate signal GW-O may have the active level and the second gate signal GW-E may have the non-active level for the first period P1′, and the first gate signal GW-O may have the inactive level while the second gate signal GW-E may have the active level for the second period P2′.

Thereafter, when the first period P1 is terminated, and the second period P2 is started, the first gate signal GW-O is shifted to be in the inactive level. Accordingly, the first red data signal R1, the first blue data signal B1, and the second green data signal G2 are respectively written onto the first red pixel PXR1, the first blue pixel PXB1, and the second green pixel PXG2, in the final stage. Meanwhile, because the second gate signal GW-E is maintained to be in the active level for the second period P2, the first green pixel PXG1, the second red pixel PXR2, and the second blue pixel PXB2 connected to the second gate line GWL-E may receive the first green data signal G1, the second red data signal R2, and the second blue data signal B2 from the first to third data lines DL1 to DL3. Thereafter, when the second period P2 is terminated, the second gate signal GW-E is shifted to be in the inactive level. Accordingly, the first green data signal G1, the second red data signal R2, and the second blue data signal B2 are respectively written onto the second red pixel PXR2, the second blue pixel PXB2, and the first green pixel PXG1, in the final stage. In this case, signals applied by the first to third data lines DL1 to DL3 for the first period P1 may be referred to as first, third, and fifth data signals, respectively. In addition, the signals applied by the first to third data lines DL1 to DL3 for the second period P2 may be referred to as second, fourth, and sixth data signals, respectively.

Accordingly, the first red pixel PXR1, the first blue pixel PXB1, and the second green pixel PXG2 generate color lights corresponding to the first red data signal R1, the first blue data signal B1, and the second green data signal G2, respectively. The first green pixel PXG1, the second red pixel PXR2, and the second blue pixel PXB2 generate color lights corresponding to the first green data signal G1, the second red data signal R2, and the second blue data signal B2. In this case, the first data signal and the second data signal applied through the first data line DL1 may include mutually different color information. The third data signal and the fourth data signal provided through the second data line DL2 may include mutually different color information. The fifth data signal and the sixth data signal applied through the third data line DL3 may include mutually different color information.

Two pixel circuits, which are connected to one data line in common, are connected to mutually different gate lines, and are activated for mutually different periods. Accordingly, two data signals sequentially applied through one data line may be written onto two pixel circuits for mutually different periods of the horizontal scan period HP. Accordingly, the number of data lines may be reduced to the half of the number of the pixel circuits located in each pixel row.

In addition, output terminals of the data driver 200 (see FIG. 1) may be connected to the data lines DL1 to DLm (see FIG. 1) in one-to-one correspondence, and the selecting circuit, which is configured to select some of the data lines, may be omitted between the data driver 200 and the data lines DL1 to DLm. Accordingly, the display panel DP (see FIG. 1), which includes the bezel that is reduced in width, may be provided.

FIG. 5 is a block diagram of pixels according to one or more embodiments of the present disclosure. FIG. 5 illustrates some pixels (e.g., first to sixth pixels PXR1a, PXR2a, PXB1a, PXB2a, PXG1a, and PXG2a) of pixels provided in a first row.

Referring to FIG. 5, among the first to sixth pixels PXR1a, PXR2a, PXB1a, PXB2a, PXG1a, and PXG2a, the first and second pixels PXR1a and PXR2a are red pixels to output a first color light, the third and fourth pixels PXB1a and PXB2a are blue pixels to output a second color light, and the fifth and sixth pixels PXG1a and PXG2a are green pixels to output a third color light.

The first gate line GWL-O and the second gate line GWL-E extend in the second direction DR2, and are spaced apart from each other in the first direction DR1. The first to sixth pixels PXR1a, PXR2a, PXB1a, PXB2a, PXG1a, and PXG2a may be arranged in the second direction DR2, and may be interposed between the first gate line GWL-O and the second gate line GWL-E. Some (e.g., the first pixel PXR1a, the third pixel PXB1a, and the sixth pixel PXG2a) of the first to sixth pixels PXR1a, PXR2a, PXB1a, PXB2a, PXG1a, and PXG2a may be connected to the first gate line GWL-O, and remaining pixels (e.g., the second, fourth, and fifth pixels PXR2a, PXB2a, and PXG1a) of the first to sixth pixels PXR1a, PXR2a, PXB1a, PXB2a, PXG1a, and PXG2a may be connected to the second gate line GWL-E.

The first to fourth data lines DL1 to DL4 extend in the first direction DR1 and are arranged in the second direction DR2. The first gate line GWL-O and the second gate line GWL-E may cross the first to fourth data lines DL1 to DL4. Each of the first to fourth data lines DL1 to DL4 may be connected to two pixels among the first to sixth pixels PXR1a, PXR2a, PXB1a, PXB2a, PXG1a, and PXG2a arranged in parallel in the second direction DR2. The first data line DL1 may be connected to the first pixel PXR1a and the second pixel PXR2a among the first to sixth pixels PXR1a, PXR2a, PXB1a, PXB2a, PXG1a, and PXG2a. The second data line DL2 may be connected to the third pixel PXB1a and the fourth pixel PXB2a among the first to sixth pixels PXR1a, PXR2a, PXB1a, PXB2a, PXG1a, and PXG2a. The third data line DL3 may be connected to the fifth pixel PXG1a among the first to sixth pixels PXR1a, PXR2a, PXB1a, PXB2a, PXG1a, and PXG2a. The fourth data line DL4 may be connected to the sixth pixel PXG2a among the first to sixth pixels PXR1a, PXR2a, PXB1a, PXB2a, PXG1a, and PXG2a.

The first to fourth data lines DL1 to DL4 may receive data signals from the data driver 200 (see FIG. 1). Each of the data signal may have a voltage level corresponding to an image signal. The data signals may include the first and second red data signals R1 and R2, zero-th to third green data signals G0 to G3, and first and second blue data signals B1 and B2. According to one or more embodiments of the present disclosure, the first red data signal R1 and the second red data signal R2 are sequentially applied to the first data line DL1, and the first blue data signal B1 and the second blue data signal B2 are sequentially applied to the second data line DL2. The zero-th green data signal G0 and the first green data signal G1 are sequentially applied to the third data line DL3, and the second green data signal G2 and the third green data signal G3 are sequentially applied to the fourth data line DL4.

The zero-th green data signal G0 may be an invalid data signal that does not provide a data signal for any one pixel.

The first pixel PXR1a may include a first pixel circuit PXC1a connected to the first data line DL1, and a light-emitting element ED1a connected to the first pixel circuit PXC1a through the connection electrodes CNE1 and CNE2 (see FIG. 2). The first light-emitting element ED1a and the first pixel circuit PXC1a may overlap each other, when viewed in a plan view.

The second pixel PXR2a may include a second pixel circuit PXC2a connected to the first data line DL1, and a second light-emitting element ED2a connected to the second pixel circuit PXC2a. The second light-emitting element ED2a and the second pixel circuit PXC2a may be connected to each other through a first bridge electrode BE1 without being overlapped with each other, when viewed in a plan view. The length of the first pixel circuit PXC1a and the length of the connection electrode CNE1 or CNE2 (see FIG. 2) for the connection of the first pixel circuit PXC1a may be shorter than the length of the first bridge electrode BE1.

However, the present disclosure is not limited thereto. For example, the first light-emitting element ED1a and the first pixel circuit PXC1a may not be overlapped with each other, when viewed in a plan view, or the second light-emitting element ED2a and the second pixel circuit PXC2a may overlap each other, when viewed in a plan view. The length of the first bridge electrode BE1, which is provided when the second light-emitting element ED2a and the second pixel circuit PXC2a may overlap each other when viewed in a plan view, may be shorter than the length of the first bridge electrode BE1 when the second light-emitting element ED2a and the second pixel circuit PXC2a are not overlapped with each other when viewed in a plan view.

The first data line DL1 is interposed between the first pixel circuit PXC1a and the second pixel circuit PXC2a. The first pixel circuit PXC1a and the second pixel circuit PXC2a may be adjacent to each other in the second direction DR2.

The third pixel PXB1a may include a third pixel circuit PXC3a connected to the second data line DL2, and a third light-emitting element ED3a connected to the third pixel circuit PXC3a. The third light-emitting element ED3a and the third pixel circuit PXC3a may overlap each other, when viewed in a plan view.

The fourth pixel PXB2a may include a fourth pixel circuit PXC4a connected to the second data line DL2 and a fourth light-emitting element ED4a connected to the fourth pixel circuit PXC4a. The fourth light-emitting element ED4a and the fourth pixel circuit PXC4a may be connected to each other through the second bridge electrode BE2 without being overlapped with each other, when viewed in a plan view.

However, the present disclosure is not limited thereto. For example, the third light-emitting element ED3a and the third pixel circuit PXC3a may not be overlapped with each other, when viewed in a plan view, or the fourth light-emitting element ED4a and the fourth pixel circuit PXC4a may overlap each other, when viewed in a plan view. The length of the second bridge electrode BE2, which is provided when the fourth light-emitting element ED4a and the fourth pixel circuit PXC4a are overlapped with each other when viewed in a plan view, may be shorter than the length of the second bridge electrode BE2 when the second light-emitting element ED4a and the second pixel circuit PXC4a are not overlapped with each other when viewed in a plan view. The second data line DL2 is interposed between the third pixel circuit PXC3a and the fourth pixel circuit PXC4a. The third light-emitting element ED3a and the fourth light-emitting element ED4a may be spaced apart from each other in the second direction DR2 while interposing the second light-emitting element ED2a between the third light-emitting element ED3a and the fourth light-emitting element ED4a, and may be adjacent to each other in the second direction DR2. According to one or more embodiments of the present disclosure, the second pixel circuit PXC2a is interposed between the first and third pixel circuits PXC1a and PXC3a, and the third pixel circuit PXC3a is interposed between the second pixel circuit PXC2a and the fourth pixel circuit PXC4a. The third light-emitting element ED3a may be interposed between the first light-emitting element ED1a and the second light-emitting element ED2a.

The fifth pixel PXG1a may include a fifth pixel circuit PXC5a connected to the third data line DL3, and a fifth light-emitting element ED5a connected to the fifth pixel circuit PXC5a. The fifth light-emitting element ED5a and the fifth pixel circuit PXC5a may overlap each other, when viewed in a plan view.

The sixth pixel PXG2a may include a sixth pixel circuit PXC6a connected to the fourth data line DL4, and a sixth light-emitting element ED6a connected to the sixth pixel circuit PXC6a. The sixth light-emitting element ED6a and the sixth pixel circuit PXC6a may not be overlapped with each other, when viewed in a plan view. However, the present disclosure is not limited thereto. For example, the fifth light-emitting element ED5a and the fifth pixel circuit PXC5a may not be overlapped with each other, when viewed in a plan view, or the sixth light-emitting element ED6a and the sixth pixel circuit PXC6a may be partially overlapped with each other, when viewed in a plan view. The fifth light-emitting element ED4a and the sixth light-emitting element ED6a may be adjacent to each other in the second direction DR2, and the fifth pixel circuit PXC5a and the sixth pixel circuit PXC6a may be spaced apart from each other in the second direction DR2 while interposing the first to fourth pixel circuits PXC1a to PXC4a between the fifth pixel circuit PXC5a and the sixth pixel circuit PXC6a. According to one or more embodiments of the present disclosure, the fifth pixel circuit PXC5a may be adjacent to the first pixel circuit PXC1a in the second direction DR2, and the sixth pixel circuit PXC6a may be adjacent to the fourth pixel circuit PXC4a in the second direction DR2. The fifth and sixth light-emitting elements ED5a and ED6a may be spaced apart from each other in the second direction DR2 while interposing the third light-emitting element ED3A between the fifth and sixth light-emitting elements ED5a and ED6a.

Referring to FIGS. 4A and 5, the first active period AP1 of the first gate signal GW-O overlaps the first period P1, and the second active period AP2 of the second gate signal GW-E overlaps the first period P1 and the second period P2. Accordingly, the first pixel PXR1a, the third pixel PXB1a, and the sixth pixel PXG2a connected to the first gate line GWL-O may receive the first red data signal R1, a first blue data signal B1, and a second green data signal G2 from the first, second, and fourth data lines DL1, DL2, and DL4, for the first period P1. Because even the second gate signal GW-E has the active level for the first period P1, even the second pixel PXR2a, the fourth pixel PXB2a, and the fifth pixel PXG1a connected to the second gate line GWL-E may receive the first red data signal R1, the first blue data signal B1, and the zero-th green data signal GO from the first to third data lines DL1 to DL3, for the first period P1, respectively.

Thereafter, when the first period P1 is terminated, and the second period P2 is started, the first gate signal GW-O is shifted to be in the inactive level. Accordingly, the first red data signal R1, the first blue data signal B1, and the second green data signal G2 are respectively written onto the first pixel PXR1a, the third pixel PXB1a, and the sixth pixel PXG2a, in the final stage. Meanwhile, because the second gate signal GW-E is maintained in the active level for the second period P2, the second pixel PXR2a, the fourth pixel PXB2a, and the fifth pixel PXG1a connected to the second gate line GWL-E may receive the second red data signal R2, the second blue data signal B2, and the first green data signal G1 from the first to third data lines DL1 to DL3, respectively. When the second period P2 is terminated, the second gate signal GW-E is shifted to be in the inactive level. Accordingly, the second red data signal R2, the second blue data signal B2, and the first green data signal G1 are respectively written onto the second pixel PXR2a, the fourth pixel PXB2a, and the fifth pixel PXG1a, in the final stage.

Accordingly, the first pixel PXR1a, the third pixel PXB1a, and the sixth pixel PXG2a generate color lights corresponding to the first red data signal R1, the first blue data signal B1, and the second green data signal G2, respectively. The second pixel PXR2a, the fourth pixel PXB2a, and the fifth pixel PXG1a generate color lights corresponding to the second red data signal R2, the second blue data signal B2, and the first green data signal G1, respectively. In this case, the first data signal and the second data signal applied through the first data line DL1 may contain the same color information. The third data signal and the fourth data signal provided through the second data line DL2 may contain the same color information. The fifth data signal and the sixth data signal applied through the third data line DL3 may contain the same color information.

However, the present disclosure is not limited thereto. The first data signal and the second data signal applied through the first data line DL1 may contain mutually different color information. The third data signal and the fourth data signal provided through the second data line DL2 may contain mutually different color information. In this case, the second data signal and the third data signal may contain the same color information. According to one or more embodiments of the present disclosure, the first data signal may contain color information about the first color light, the second and third data signals may contain color information about the second color light, and the fourth data signal may contain color information about a third color light. According to one or more embodiments of the present disclosure, the first data signal may contain color information about the third color light, the second and third data signals may contain color information about the second color light, and the fourth data signal may contain color information about the first color light.

Referring to FIG. 5, the first data line DL1 may receive only the red data signals R1 and R2 having red color information, and the second data line DL2 may receive only blue data signals B1 and B2 having blue color information. The third and fourth data lines DL3 and DL4 may receive only green data signals G0, G1, G2, and G3 having green color information. As described above, when the color information contained in the data signal applied to each data line may be maintained with the same color information without being varied over time, power consumption may be more reduced, as compared to when the color information contained in the data signal is varied over time.

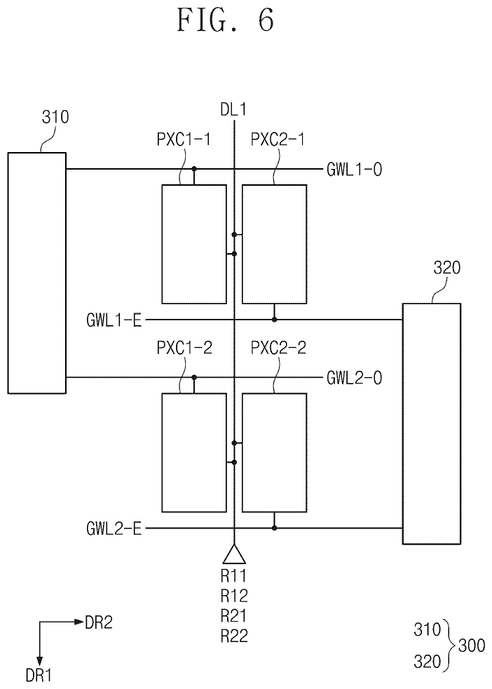

FIG. 6 is a block diagram illustrating pixel circuits and gate drivers according to one or more embodiments of the present disclosure. FIG. 6 illustrates some pixels (e.g., a (1-1)-th pixel circuit PXC1-1 and a (2-1)-th pixel circuit PXC2-1) of pixel circuits located in a first row, and illustrates some pixels (e.g., a (1-2)-th pixel circuit PXC1-2 and a (2-2)-th pixel circuit PXC2-2) of pixel circuits arranged in a second row.

Referring to FIG. 6, according to one or more embodiments of the present disclosure, the gate driver 300 may include a first gate driver 310 and a second gate driver 320. The first gate driver 310 may be connected to first gate lines GWL1-O and GWL2-O, and the second gate driver 320 may be connected to second gate lines GWL1-E and GWL2-E.

The first gate lines GWL1-O and GWL2-O may be alternately located in the first direction DR1, and the second gate lines GWL1-E and GWL2-E may be alternately located in the first direction DR1. The (1-1)-th gate line GWL1-O may be connected to a (1-1)-th pixel circuit PXC1-1 of pixel circuits located in the first row, and the (2-1)-th gate line GWL2-O may be connected to a (2-1)-th pixel circuit PXC2-1 of pixel circuits located in the first row. The (1-1)-th gate line GWL1-O and the (2-1)-th gate line GWL1-E may be spaced apart from each other in the first direction DR1, while interposing the (1-1)-th pixel circuit PXC1-1 and the (2-1)-th pixel circuit PXC2-1 between the (1-1)-th gate line GWL1-O and the (2-1)-th gate line GWL1-E.

The (1-2)-th gate line GWL2-O may be connected to the (1-2)-th pixel circuit PXC1-2 of the pixel circuits located in the second row, and the (2-2)-th gate line GWL2-E may be connected to the (2-2)-th pixel circuit PXC2-2 of the pixel circuits located in the second row. The (1-2)-th gate line GWL2-O and the (2-2)-th gate line GWL2-E may be spaced apart from each other in the first direction DR1, while interposing the (1-2)-th pixel circuit PXC1-2 and the (2-2)-th pixel circuit PXC2-2 between the (1-2)-th gate line GWL2-O and the (2-2)-th gate line GWL2-E. In this case, the (2-1)-th gate line GWL1-E and the (1-2)-th gate line GWL2-O are adjacent to each other in the first direction DR1.

The first data line DL1 may extend in the first direction DR1. The (1-1)-th, (1-2)-th, (2-1)-th, and (2-2)-th pixel circuits PXC1-1, PXC1-2, PXC2-1, and PXC2-2 may be connected to the first data line DL1. The first data line DL1 may receive the data signal from the data driver 200 (see FIG. 1). All pixels connected to the first data line DL1 may receive data signals R11, R12, R21, and R22 having the same color information (for example, red color information). According to one or more embodiments of the present disclosure, the data signals may include the (1-1)-th, (1-2)-th, (2-1)-th, and (2-2)-th red data signals R11, R12, R21, and R22. According to one or more embodiments of the present disclosure, the (1-1)-th red signal R11, the (1-2)-th red signal R12, the (2-1)-th red signal R21, and the (2-2)-th red signal R22 may be sequentially applied to the first data line DL1.

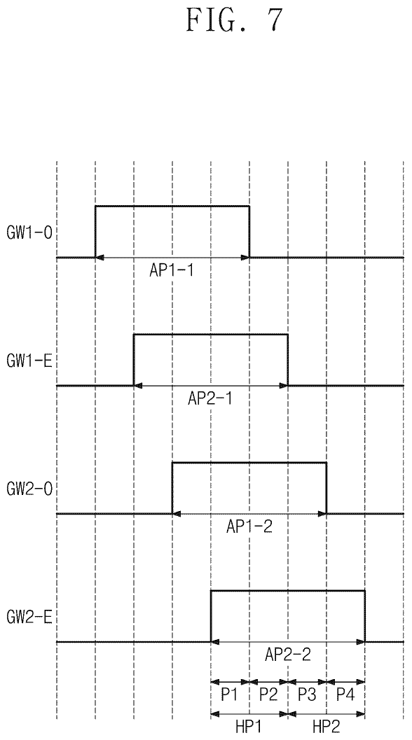

FIG. 7 is a timing diagram illustrating first and second gate signals respectively applied to first and second gate lines according to one or more embodiments of the present disclosure.

Referring to FIGS. 6 and 7, a (1-1)-th gate signal GW1-O may include a (1-1)-th active period AP1-1 having an active level, and a (2-1)-th signal GW1-E may include a (2-1)-th active period AP2-1 having the active level. A (1-2)-th gate signal GW2-O may include a (1-2)-th active period AP1-2 having an active level, and a (2-2)-th signal GW2-E may include a (2-2)-th active period AP2-2 having the active level. The (1-1)-th active period AP1-1 may overlap the (2-1)-th active period AP2-1, and the (1-2)-th active period AP1-2 may overlap the (2-2)-th active period AP2-2. Each of the (1-1)-th active period AP1-1, (1-2)-th active period AP1-2, the (2-1)-th active period AP2-1, and the (2-2)-th active period AP2-2 may have a duration corresponding to ‘k’ times first and second horizontal scan periods HP1 and HP2. The first horizontal scan period HP1 may be defined as a period in which a data signal is written onto the first pixel row, and the second horizontal scan period HP2 may be defined as a period in which a data signal is written onto a second pixel row.

The (1-1)-th gate signal GW1-O and the (1-2)-th gate signal GW2-O may be sequentially output from the first gate driver 310, and the (1-2)-th gate signal GW2-O may be delayed from the (1-1)-th gate signal GW1-O by one horizontal scan period HP. The (2-1)-th gate signal GW1-E and the (2-2)-th gate signal GW2-E may be sequentially output from the second gate driver 320, and the (2-2)-th gate signal GW2-E may be delayed from the (2-1)-th gate signal GW1-E by one horizontal scan period HP. The (2-1)-th gate signal GW1-E is delayed from the (1-1)-the gate signal GW1-O by a half of one horizontal scan period, and the (2-2)-th gate signal GW2-E may be delayed from the (1-2)-th gate signal GW2-O by a half of one horizontal scan period.

The first horizontal scan period HP1 may include a first period P1 and a second period P2. The second horizontal scan period HP2 may include a third period P3 and a fourth period P4. The (1-1)-th active period AP1-1 of the (1-1)-th gate signal GW1-O overlaps the first period P1, and the (2-1)-th active period AP2-1 of the (2-1)-th gate line GW1-E overlaps the first period P1 and the second period P2. The (1-2)-th active period AP1-2 of the (1-2)-th gate signal GW2-O overlaps the first to third periods P1 to P3, and the (2-2)-th active period AP2-2 of the (2-2)-th gate line GW2-E overlaps the first to fourth periods P1 to P4.

Because all the (1-1)-th, (1-2)-th, (2-1)-th, and (2-2)-th gate signals GW1-O, GW1-O, GW1-E, and GW2-E have active levels for the first period P1, the (1-1)-th, (1-2)-th, (2-1)-th, and (2-2)-th pixel circuits PXC1-1, PXC1-2, PXC2-1, and PXC2-2, which receive the (1-1)-th, (1-2)-th, (2-1)-th, and (2-2)-th gate signals GW1-O, GW2-O, GW1-E, and GW2-E, respectively, may receive the (1-1)-th red data signal R11 from the first data line DL1.

Thereafter, when the second period P2 is started after the first period P1 is terminated, because the (1-1)-th gate signal GW1-O is shifted to be in the inactive level, the (1-1)-th red data signal R11 is written on the (1-1)-th pixel circuit PXC1-1 in the final stage. Meanwhile, because the (1-2)-th, (2-1)-th, and (2-2)-th gate signals GW2-O, GW1-E, and GW2-E have active levels for the second period P2, the (1-2)-th, (2-1)-th, and (2-2)-th pixel circuits PXC1-2, PXC2-1, and PXC2-2, which receive the (1-2)-th, (2-1)-th, and (2-2)-th gate signals GW2-O, GW1-E, and GW2-E, respectively, may receive the (1-2)-th red data signal R12 from the first data line DL1.

Thereafter, when the third period P3 is started after the second period P2 is terminated, because the (2-1)-th gate signal GW1-E is shifted to be in the inactive level, the (1-2)-th red data signal R12 is written on the (2-1)-th pixel circuit PXC2-1 in the final stage. Meanwhile, because the (1-2)-th, and (2-2)-th gate signals GW2-O, and GW2-E are maintained in the active level for the third period P3, the (1-2)-th and the (2-2)-th pixel circuits PXC1-2, and PXC2-2, which receive the (1-2)-th and the (2-2)-th gate signals GW2-O, and GW2-E, respectively, may receive the (2-1)-th red data signal R21 from the first data line DL1.

Thereafter, when the fourth period P4 is started after the third period P3 is terminated, because the (1-2)-th gate signal GW2-O is shifted to be in the inactive level, the (2-1)-th red data signal R21 is written on the (1-2)-th pixel circuit PXC1-2 in the final stage. Meanwhile, because the (2-2)-th gate signals GW2-E is maintained in the active level for the fourth period P4, the (2-2)-th pixel circuit PXC2-2, which receives the (2-2)-th gate signal GW2-E, respectively, may receive the (2-2)-th red data signal R22 from the first data line DL1.

Thereafter, when the fourth period P4 is terminated, because the (2-2)-th gate signal GW2-E is shifted to be in the inactive level, the (2-2)-th red data signal R22 is written on the (2-2)-th pixel circuit PXC2-2 in the final stage.

The (1-1)-th, (1-2)-th, (2-1)-th, and (2-2)-th red data signals R11, R12, R21, and R22 sequentially applied to the first data line DL1 may be applied to the (1-1)-th, (1-2)-th, (2-1)-th, and (2-2)-th pixel circuits PXC1-1, PXC1-2, PXC2-1, and PXC2-2 for the first to fourth periods P1 to P4 classified depending on whether the (1-1)-th and (1-2)-th gate signals GW1-O and GW2-O, and the (2-1)-th and (2-2)-th gate signals GW1-E and GW2-E are activated. The first data line DL1 may receive red data signals R11, R12, R21, and R22 having red color information. As described above, when the color information of the data signal applied to the data line may be maintained with the same color information without being varied over time, power consumption may be further reduced, as compared to when the color information of the data signal is varied over time.

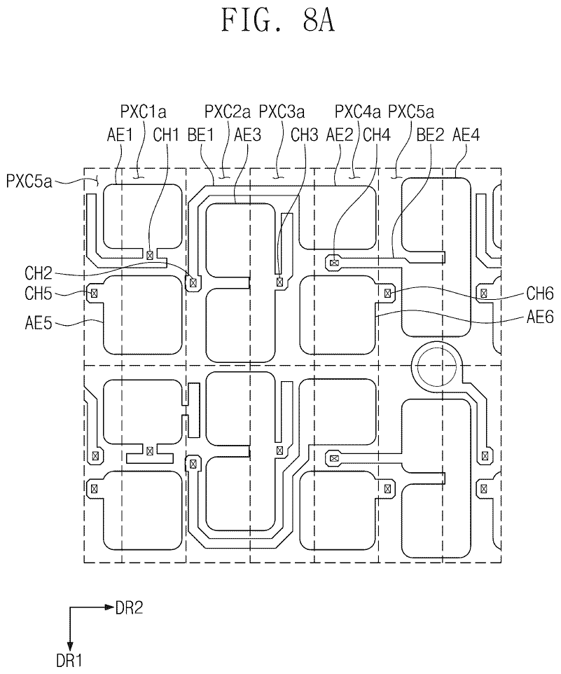

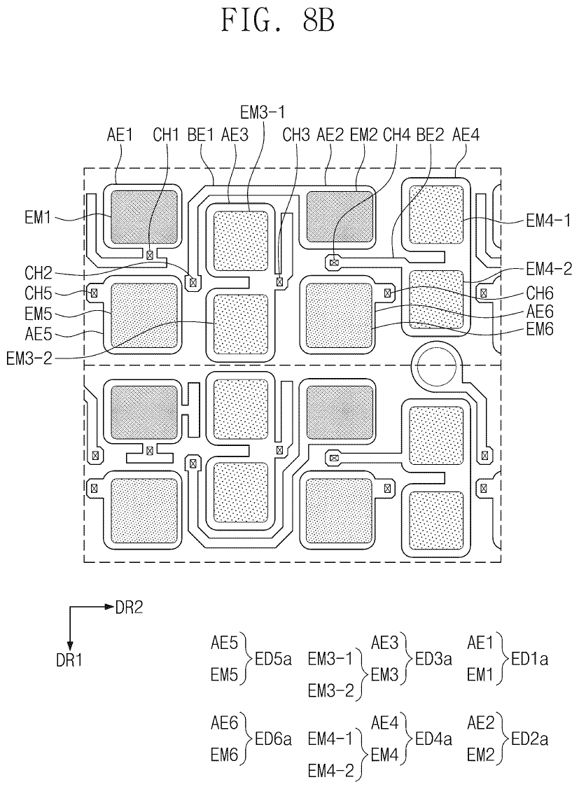

FIG. 8A is a plan view illustrating a plurality of pixels according to one or more embodiments of the present disclosure. FIG. 8B is a plan view of light-emitting elements according to one or more embodiments of the present disclosure.

Referring to FIGS. 8A and 8B, first to sixth light-emitting elements ED1a to ED6a may be connected to first to sixth pixel circuits PXC1a to PXC6a through first to sixth contact holes CH1 to CH6, respectively.

The arrangement relationships between the first to sixth light-emitting elements ED1a to ED6a and the first to sixth pixel circuits PXC1a to PXC6a in FIG. 8A are the same as the arrangement relationships between the first to sixth light-emitting elements ED1a to ED6a and the first to sixth pixel circuits PXC1a to PXC6a described with reference to FIG. 5. The first to sixth contact holes CH1 to CH6 may be respectively overlapped with the first to sixth pixel circuits PXC1a to PXC6a, when viewed in a plan view.

The first to sixth light-emitting elements ED1a to ED6a include first to sixth anode electrodes AE1 to AE6 and first to sixth light-emitting layers EM1 to EM6. The first to sixth anode electrodes AE1 to AE6 are overlapped with the first to sixth light-emitting layers EM1 to EM6, respectively, when viewed in a plan view.

The first light-emitting element ED1a may be connected to the first pixel circuit PXC1a through the first contact hole CH1 overlapped with the first light-emitting element ED1a, when viewed in a plan view. The second light-emitting element ED2a may be connected to the second pixel circuit PXC2a through the second contact hole CH2 overlapped with the second light-emitting element ED2a, when viewed in a plan view. The second light-emitting element ED2a may include the first bridge electrode BE1. As the second light-emitting element ED2a and the second pixel circuit PXC2a may be spaced apart from each other by a corresponding distance, the second light-emitting element ED2a may be connected to the second pixel circuit PXC2a through the second contact hole CH2 by extending the second anode electrode AE2 through the first bridge electrode BE1.

The third light-emitting element ED3a may be connected to the third pixel circuit PXC3a through the third contact hole CH3 overlapped with the third light-emitting element ED3a, when viewed in a plan view. The fourth light-emitting element ED4a may be connected to the fourth pixel circuit PXC4a through the fourth contact hole CH4. The fourth light-emitting element ED4a may include the second bridge electrode BE2. As the fourth light-emitting element ED4a and the fourth pixel circuit PXC4a may be spaced apart from each other by a corresponding distance, the fourth light-emitting element ED4a may be connected to the fourth pixel circuit PXC4a through the fourth contact hole CH4 by extending the fourth anode electrode AE4 through the second bridge electrode BE2.

The fifth light-emitting element ED5a may be connected to the fifth pixel circuit PXC5a through the fifth contact hole CH5, and the sixth light-emitting element ED6a may be connected to the sixth pixel circuit PXC6a through the sixth contact hole CH6.

The third light-emitting element ED3a may include the third light-emitting layer EM3 and the third anode electrode AE3. The third light-emitting layer EM3 may include a (3-1)-th light-emitting layer EM3-1 and a (3-2)-th light-emitting layer EM3-2. The (3-1)-th light-emitting layer EM3-1 and the (3-2)-th light-emitting layer EM3-2 may be spaced apart from each other in the first direction DR1. However, the present disclosure is not limited thereto. Alternatively, the (3-1)-th light-emitting layer EM3-1 and the (3-2)-th light-emitting layer EM3-2 may be formed integrally with each other. The fourth light-emitting element ED4a may include a fourth light-emitting layer EM4 and a fourth anode electrode AE4. The fourth light-emitting element EM4 may include a (4-1)-th light-emitting layer EM4-1 and a (4-2)-th light-emitting layer EM4-2. The (4-1)-th light-emitting layer EM4-1 and the (4-2)-th light-emitting layer EM4-2 may be spaced apart from each other in the first direction DR1. However, the present disclosure is not limited thereto. Alternatively, the (4-1)-th light-emitting layer EM4-1 and the (4-2)-th light-emitting layer EM4-2 may be formed integrally with each other.

In FIG. 8B, the first bridge electrode BE1 is formed integrally with the second anode electrode AE2, and the second bridge electrode BE2 is formed integrally with the fourth anode electrode AE4. In other words, the first and second bridge electrodes BE1 and BE2 may be located on a layer the same as a layer for the second and fourth anode electrodes AE2 and AE4. However, the present disclosure is not limited thereto. For example, the first and second bridge electrodes BE1 and BE2 may be located on a layer that is different from the layer for the second and fourth anode electrodes AE2 and AE4.

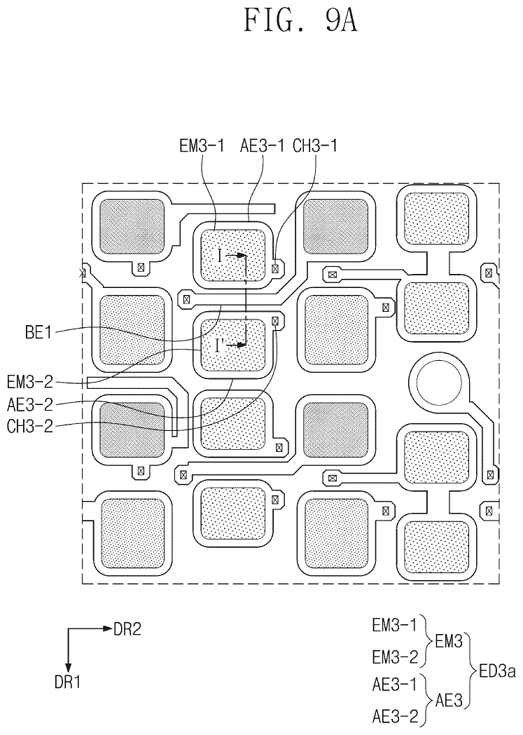

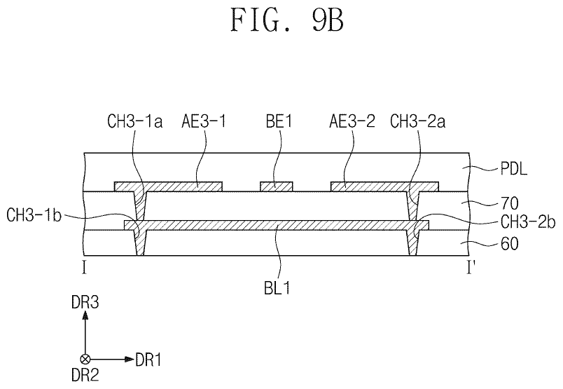

FIG. 9A is a plan view of light-emitting elements according to one or more embodiments of the present disclosure. FIG. 9B is a cross-sectional view of a third light-emitting element taken along line I-I′ of FIG. 9A.

Referring to FIGS. 9A and 9B, the third light-emitting element ED3a includes the third light-emitting layer EM3 and the third anode electrode AE3, and the third anode electrode AE3 includes a (3-1)-th anode electrode AE3-1 (referred to as a “first sub-anode electrode”) and a (3-2)-th anode electrode AE3-2 (referred to as a “second sub-anode electrode”). The third light-emitting layer EM3 includes the (3-1)-th light-emitting layer and the (3-2)-th light-emitting layer. The (3-1)-th anode electrode AE3-1 may overlap the (3-1)-th light-emitting layer EM3-1 when viewed in a plan view, and the (3-2)-th anode electrode AE3-2 may overlap the (3-2)-th light-emitting layer EM3-2, when viewed in a plan view.

The (3-1)-th anode electrode AE3-1 and the (3-2)-th anode electrode AE3-2 may be connected to a first bridge line BL1 through a (3-1a)-th contact hole CH3-1a and a (3-2a)-th contact hole CH3-2a formed through, or defined by, the seventh insulating layer 70. The first bridge line BL1 may connect the (3-1)-th anode electrode AE3-1 and the (3-2)-th anode electrode AE3-2 to the third pixel circuit PXC3a through a (3-1b)-th contact hole CH3-1b and a (3-2b)-th contact hole CH3-2b, which are formed through the sixth insulating layer 60.

In FIG. 9A, the first bridge electrode BE1 is formed integrally with the second anode electrode AE2, and the second bridge electrode BE2 is formed integrally with the fourth anode electrode AE4. In other words, the first and second bridge electrodes BE1 and BE2 may be located on a layer the same as a layer for the second and fourth anode electrodes AE2 and AE4. However, the present disclosure is not limited thereto. For example, the first and second bridge electrodes BE1 and BE2 may be located on a layer that is different from the layer for the second and fourth anode electrodes AE2 and AE4.

The first bridge electrode BE1 may be interposed between the (3-1)-th anode electrode AE3-1 and the (3-2)-th anode electrode AE3-2. The first bridge electrode BE1 may be located on a layer (e.g., the seventh insulating layer 70) the same as the layers for the (3-1)-th anode electrode AE3-1 and the (3-2)-th anode electrode AE3-2. However, the present disclosure is not limited thereto. The first bridge electrode BE1 may be located on a layer that is different from the layers for the (3-1)-th anode electrode AE3-1 and the (3-2)-th anode electrode AE3-2.

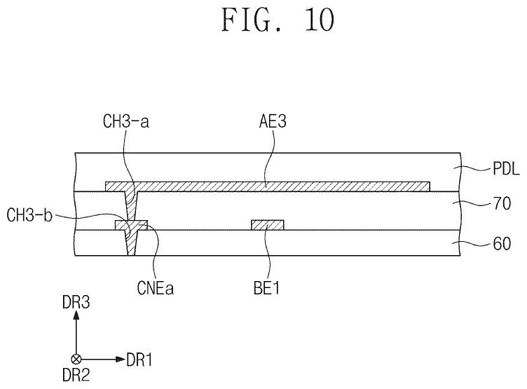

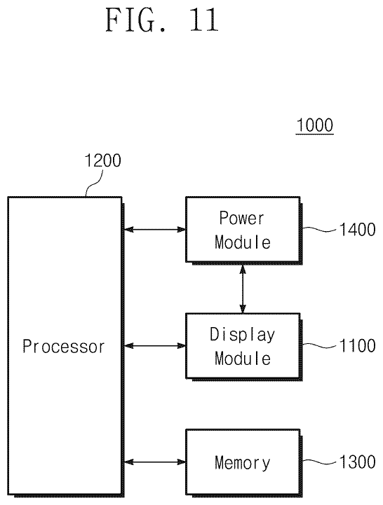

FIG. 10 is a cross-sectional view of a third light-emitting element according to one or more embodiments of the present disclosure.

Referring to FIGS. 8B and 10, the third light-emitting element ED3a may include one third anode electrode AE3.

The first bridge electrode BE1 may overlap the third anode electrode AE3, when viewed in a plan view. In this case, the first bridge electrode BE1 may be located on a layer that is different from a layer for the third anode electrode AE3. For example, the first bridge electrode BE1 may be located on the sixth insulating layer 60, and the third anode electrode AE3 may be located on the seventh insulating layer 70. The third anode electrode AE3 may be connected to an a-th connection electrode CNEa, which includes a (3-a)-th contact hole CH3-a, through the (3-a)-th contact hole CH3-a formed through the seventh insulating layer 70. The a-th connection electrode CNEa may connect the third anode electrode AE3 to the third pixel circuit PXC3a through a (3-b)-th contact hole CH3-b formed through the sixth insulating layer 60.

According to the present disclosure, the output terminals of the data driver may be connected to the data lines in one-to-one correspondence, and the selecting circuit, which is to select some of the data lines, may be omitted between the data driver and the data lines. Accordingly, the display panel including the bezel reduced in width may be provided.

In addition, the color information of the data signal applied to each data line may be substantially identically maintained without being significantly varied over time. Accordingly, power consumption may be more reduced, as compared to when the color information of the data signal is varied over time.

The display device may be applied to various electronic devices. The electronic device may include the display device and may further include a module or device having additional functions in addition to the display device.

FIG. 11 is a block diagram illustrating the electronic device according to an embodiment of the present disclosure. Referring to FIG. 11, the electronic device 1000 may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), and a controller. The processor 1200 may control the operation of the display device according to embodiments of the present disclosure.

The memory 1300 may store data information required for the operation of the processor 1200 or the display module 1100. When the processor 1200 executes an application stored in the memory 1300, an image data signal and/or an input control signal may be transmitted to the display module 1100, and the display module 1100 may process the received signals to output image information through a display screen.

The power module 1400 may include a power supply module, such as a power adapter or a battery device, and a power conversion module that converts power supplied by the power supply module to generate power required for the operation of the electronic device 1000.

The electronic device 1000 may include the display device according to the embodiments, and at least one of components of the electronic device 1000 may be included in the display device according to embodiments. In addition, among individual modules that are functionally included within a single module, some may be included in the display device while others may be provided separately from the display device. As an example, the display device may include the display module 1100, and the processor 1200, the memory 1300, and the power module 1400 may be provided as separate devices within the electronic device 1000, rather than being included in the display device.

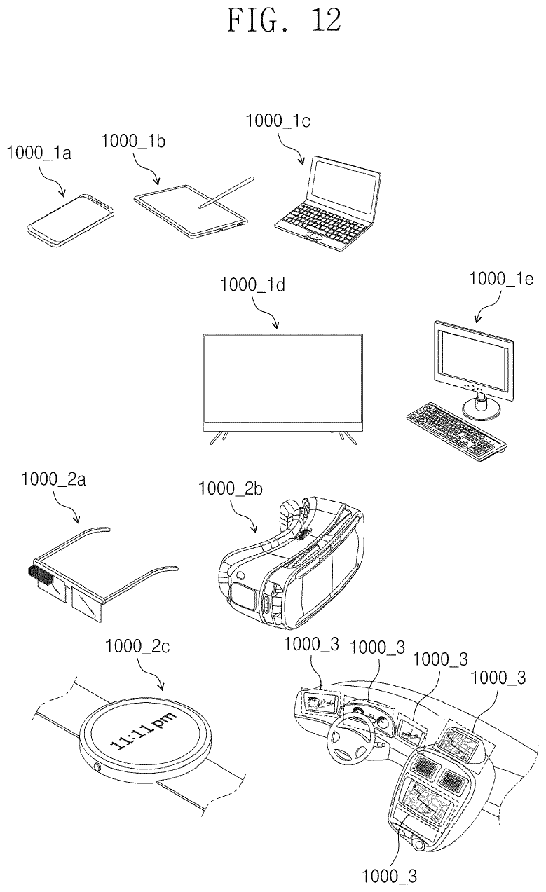

FIG. 12 are schematic views illustrating electronic devices according to various embodiments of the present disclosure.

Referring to FIG. 12, various electronic devices to which the display device according to embodiments is applied may include an electronic device for displaying images, such as a smartphone 1000_1a, a tablet PC 1000_1b, a laptop computer 1000_1c, a television 1000_1d, a desktop monitor 1000_1e, etc., a wearable electronic device including a display module, such as a smart glasses 1000_2a, a head-mounted display 1000_2b, a smartwatch 1000_2c, etc., and an in-vehicle electronic device 1000_3 including a display module, such as an instrument panel, a center fascia, a dashboard-mounted center information display (CID), a room mirror display, etc.

Although one or more embodiments of the present disclosure has been described for illustrative purposes, those skilled in the art will appreciate that various modifications, and substitutions are possible, without departing from the scope and spirit of the present disclosure as disclosed in the accompanying claims. Accordingly, the technical scope of the present disclosure is not limited to the detailed description of this specification, but should be defined by the claims, with functional equivalents thereof to be included therein.

What is claimed is:

1. A display device comprising:
a first data line extending in a first direction, and configured to sequentially receive a first data signal and a second data signal;
a first gate line configured to receive a first gate signal activated for a first active period;
a second gate line configured to receive a second gate signal activated for a second active period;
a first pixel comprising a first pixel circuit connected to the first data line and to the first gate line, and a first light-emitting element connected to the first pixel circuit; and
a second pixel comprising a second pixel circuit connected to the first data line and to the second gate line, and a second light-emitting element connected to the second pixel circuit,
wherein the first pixel circuit and the second pixel circuit are in a same pixel row adjacent to each other in a second direction crossing the first direction.

2. The display device of claim 1, wherein a horizontal scan period is defined by the first active period and the second active period, and comprises a first period and a second period.

3. The display device of claim 2, wherein the first active period and the second active period have a duration corresponding to ‘k’ times the horizontal scan period, ‘k’ being a natural number equal to or greater than 1.

4. The display device of claim 2, wherein the first active period and the second active period overlap,
wherein the first gate signal and the second gate signal have an active level for the first period, and
wherein the first gate signal has an inactive level, and the second gate signal has an active level, for the second period.

5. The display device of claim 2, wherein the first active period and the second active period are separate,
wherein the first gate signal has an active level, and the second gate signal has an inactive level, for the first period, and
wherein the first gate signal has an inactive level, and the second gate signal has an active level, for the second period.

6. The display device of claim 2, wherein the first data line is configured to apply the first data signal to the first pixel circuit and to the second pixel circuit for the first period, and
wherein the first data line is configured to apply the second data signal to the second pixel circuit for the second period.

7. The display device of claim 4, wherein color information of the first data signal is different from color information of the second data signal.

8. The display device of claim 1, wherein the first pixel circuit is connected to the first light-emitting element through a connection electrode,
wherein the second pixel circuit is connected to the second light-emitting element through a bridge electrode, and
wherein the bridge electrode is longer than the connection electrode.

9. The display device of claim 8, wherein the second light-emitting element comprises an anode electrode integral with the bridge electrode.

10. The display device of claim 8, wherein the second light-emitting element comprises an anode electrode at a different layer from the bridge electrode.

11. The display device of claim 2, further comprising:
a second data line extending in the first direction, and configured to sequentially receive a third data signal and a fourth data signal;
a third pixel comprising a third pixel circuit connected to the second data line and to the first gate line, and a third light-emitting element connected to the third pixel circuit; and
a fourth pixel comprising a fourth pixel circuit connected to the second data line and the second gate line, and a fourth light-emitting element connected to the fourth pixel circuit.

12. The display device of claim 11, wherein the second data line is configured to apply the third data signal to the third pixel circuit and to the fourth pixel circuit for the first period, and
wherein the second data line is configured to apply the fourth data signal to the fourth pixel circuit for the second period.

13. The display device of claim 12, wherein color information of the third data signal is different from color information of the fourth data signal.

14. The display device of claim 12, wherein color information of the third data signal is the same as color information of the fourth data signal.

15. An electronic device comprising:
a display device for providing an image; and
a processor to control an operation of the display device
wherein the display device comprises:
a first data line extending in a first direction, and configured to sequentially receive a first data signal comprising color information and a second data signal comprising color information that is the same as the color information of the first data signal;
a first gate line configured to receive a first gate signal;
a second gate line configured to receive a second gate signal;
a first pixel comprising a first pixel circuit connected to the first data line and to the first gate line, and a first light-emitting element connected to the first pixel circuit through a connection electrode; and
a second pixel comprising a second pixel circuit connected to the first data line and to the second gate line and adjacent to the first pixel circuit in a same pixel row in a second direction crossing the first direction, and a second light-emitting element connected to the second pixel circuit through a bridge electrode that is longer than the connection electrode.

16. The electronic device of claim 15, further comprising:
a second data line extending in the first direction, and configured to sequentially receive a third data signal and a fourth data signal;
a third pixel comprising a third pixel circuit connected to the second data line and to the first gate line, and a third light-emitting element connected to the third pixel circuit;
a fourth pixel comprising a fourth pixel circuit connected to the second data line and to the second gate line, and a fourth light-emitting element connected to the fourth pixel circuit; and
wherein the third light-emitting element comprises a first sub-anode electrode and a second sub-anode electrode.

17. The electronic device of claim 16, wherein color information of the third data signal is the same as color information of the fourth data signal.

18. The electronic device of claim 16, wherein the bridge electrode is at a same layer as the first sub-anode electrode and the second sub-anode electrode.

19. The electronic device of claim 17, wherein the bridge electrode is at a different layer from a layer from the first sub-anode electrode and the second sub-anode electrode.

20. A display device comprising:
a first data line configured to sequentially receive a first data signal and a second data signal;
a second data line configured to sequentially receive a third data signal and a fourth data signal;
a first gate line configured to receive a first gate signal activated for a first active period;
a second gate line configured to receive a second gate signal activated for a second active period;
a first pixel comprising a first pixel circuit connected to the first data line and to the first gate line, and a first light-emitting element connected to the first pixel circuit;
a second pixel comprising a second pixel circuit connected to the first data line and to the second gate line, and a second light-emitting element connected to the second pixel circuit;
a third pixel comprising a third pixel circuit connected to the second data line and to the first gate line, and a third light-emitting element connected to the third pixel circuit; and
a fourth pixel comprising a fourth pixel circuit connected to the second data line and to the second gate line, and a fourth light-emitting element connected to the fourth pixel circuit,
wherein color information of the first data signal is different from color information of the second data signal, which is the same as color information contained in the third data signal, and
wherein color information of the fourth data signal is different from the color information of the first data signal and the color information of the second data signal.
